(19) United States
(12) Patent Application Publication
(10) Pub. No.: US 2016/0351695 A1
(43) Pub. Date: Dec. 1, 2016

(54) SEMICONDUCTOR DEVICE AND MANUFACTURING METHOD THEREOF

(71) Applicant: KABUSHIKI KAISHA TOSHIBA, Tokyo (JP)

(72) Inventor: Masakazu GOTO, Yokohama Kanagawa (JP)

(73) Assignee: KABUSHIKI KAISHA TOSHIBA, Tokyo (JP)

(21) Appl. No.: 14/841,510

(22) Filed: Aug. 31, 2015

(30) Foreign Application Priority Data
May 25, 2015 (JP) 2015-105782

(51) Int. Cl. H01L 29/66; H01L 21/266; H01L 21/265; H01L 29/786

(52) U.S. Cl. CPC H01L 29/66977; H01L 29/78696; H01L 29/78618; H01L 21/266; H01L 21/26513; H01L 29/66742

(57) ABSTRACT

A semiconductor device according to an embodiment includes a semiconductor layer. A gate dielectric film is provided on the semiconductor layer. A gate electrode is provided on the semiconductor layer via the gate dielectric film. A first conductivity-type source layer is provided in the semiconductor layer on a side of one end of the gate electrode. A second conductivity-type drain layer is provided in the semiconductor layer on a side of the other end of the gate electrode. The drain layer does not face a bottom surface of the gate electrode. A first diffusion layer of the first conductivity-type is provided at least in a part of the semiconductor layer between a first portion of the semiconductor layer and the drain layer. The first portion faces the bottom surface of the gate electrode.

### CROSS REFERENCE TO RELATED APPLICATIONS

This application is based upon and claims the benefit of priority from the prior Japanese Patent Application No. 2015-105782, filed on May 25, 2015, the entire contents of which are incorporated herein by reference.

### FIELD

The embodiments of the present invention relate to a semiconductor device and manufacturing method thereof.

### BACKGROUND

In recent years, a TFET (Tunnel Field-Effect Transistor) using a quantum-mechanical effect of electrons has been developed. The TFET is brought to an on-state when a voltage is applied to a gate electrode thereof to cause BTBT (Band To Band Tunneling) between a source and a channel thereof.

A drain offset structure is developed to suppress a leakage current in an off-state (an off-leakage current) between a drain and a gate of the TFET. In the drain offset structure, an end of a drain layer is separated from an end of the gate electrode in a channel length direction to prevent the drain layer from facing a bottom surface of the gate electrode.

However, if an impurity concentration of a channel portion is lowered to decrease a threshold voltage, a depletion layer from the drain layer is likely to extend to below the gate electrode. This leads to increase of the leakage current between the drain and the gate. Therefore, even in the TFET having the drain offset structure, an effect of suppressing the off-leakage current is difficult to achieve if the impurity concentration of the channel portion is lowered to decrease the threshold voltage. That is, it is difficult to achieve both suppression of the off-leakage current and decrease of the threshold voltage in the conventional TFET.

### BRIEF DESCRIPTION OF THE DRAWINGS

FIG. 1 is a schematic cross-sectional view showing an example of a configuration of an N-TFET 100 according to a first embodiment;

FIG. 2 is a graph showing a relation between the impurity concentration of the pocket layer 70 and the leakage current;

FIG. 3 is a graph showing a relation between the off-leakage current and the on-state current;

FIGS. 4A to 8B are cross-sectional views showing an example of a manufacturing method of the N-TFET 100 according to the first embodiment; and

FIGS. 9A and 9B are cross-sectional views showing an example of a manufacturing method of an N-TFET 100 according to a second embodiment.

### DETAILED DESCRIPTION

Embodiments will now be explained with reference to the accompanying drawings. The present invention is not limited to the embodiments. In the embodiments, “an upper direction” or “a lower direction” refers to a relative direction when a direction of a surface of a semiconductor layer on which semiconductor elements are provided is assumed as “an upper direction”. Therefore, the term “upper direction” or “lower direction” occasionally differs from an upper direction or a lower direction based on a gravitational acceleration direction.

A semiconductor device according to an embodiment includes a semiconductor layer. A gate dielectric film is provided on the semiconductor layer. A gate electrode is provided on the semiconductor layer via the gate dielectric film. A first conductivity-type source layer is provided in the semiconductor layer on a side of one end of the gate electrode. A second conductivity-type drain layer is provided in the semiconductor layer on a side of the other end of the gate electrode. The drain layer does not face a bottom surface of the gate electrode. A first diffusion layer of the first conductivity-type is provided at least in a part of the semiconductor layer between a first portion of the semiconductor layer and the drain layer. The first portion faces the bottom surface of the gate electrode.

### First Embodiment

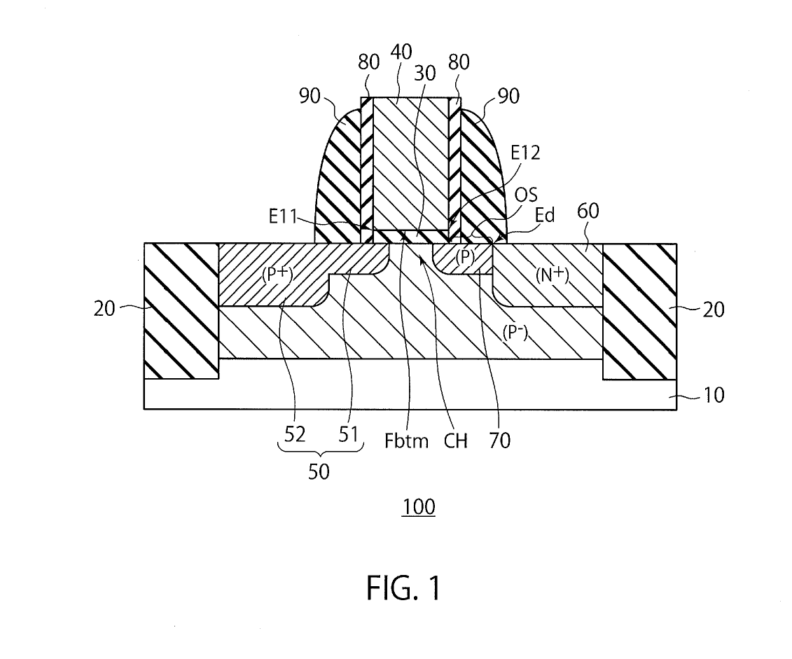

FIG. 1 is a schematic cross-sectional view showing an example of a configuration of an N-TFET 100 according to a first embodiment. The TFET 100 can be used for a logic semiconductor integrated circuit such as a microprocessor or an ASIC (Application Specific Integrated Circuit). In FIG. 1, illustrations of an interlayer dielectric film and a wiring structure on a gate electrode 40, a source layer 50, and a drain layer 60 are omitted.

The TFET 100 includes a semiconductor layer 10, an element isolation part 20, a gate dielectric film 30, the gate electrode 40, the source layer 50, the drain layer 60, a pocket layer 70, sidewall films 80, and sidewall films 90.

The semiconductor layer 10 can be a SOI (Silicon On Insulator) layer provided in a SOI substrate. The semiconductor layer 10 can be a SiGe layer of a SiGe-OI substrate, a Ge layer of a Ge-OI substrate, a silicon layer formed using a silicon substrate, or a semiconductor layer using a group III-V compound semiconductor substrate other than the SOI layer of the SOI substrate. Alternatively, the semiconductor layer 10 can be a semiconductor layer epitaxially grown on an arbitrary substrate.

The element isolation part 20 is provided in the semiconductor layer 10 to electrically isolate adjacent active areas from each other. For example, the element isolation part 20 is STIs (Shallow Trench Isolation) and is formed using an insulating film such as a silicon dioxide film.

The gate dielectric film 30 is an insulating film provided on a surface of the semiconductor layer 10 and is formed of, for example, a silicon dioxide film or a dielectric material having a higher dielectric constant than that of the silicon dioxide film.

The gate electrode 40 is provided on the semiconductor layer 10 via the gate dielectric film 30 (or with the gate dielectric film 30 interposed therebetween). A conducting material such as N-doped polysilicon or metal is used as the gate electrode 40.

The source layer 50 of a P⁺-type is provided in the semiconductor layer 10 on the side of one end E11 of the gate electrode 40. The source layer 50 is a P-type (first conductivity type) semiconductor layer containing a high concentration (equal to or higher than about 10²⁰/cm³, for example) of P-type impurities (boron, for example). The source layer 50 includes an extension region 51 and a source region 52. The extension region 51 and the source region 52 are electrically connected to each other to constitute the source layer 50.

The extension region 51 is provided in a surface region of the semiconductor layer 10 between the source region 52 and a channel portion CH and is adjacent to the source region 52. The extension region 51 is formed in such a manner that a bottom surface of the extension region 51 is located at a shallower position than that of the source region 52. The extension region 51 extends to just below a bottom surface Fbtm of the gate electrode 40 and faces the bottom surface Fbtm. That is, when viewed from above the surface of the semiconductor layer 10, the extension region 51 is overlapped with the bottom surface Fbtm of the gate electrode 40. The configuration of the source layer 50 is not limited thereto and other configurations can be applied.

The drain layer 60 of an N⁺-type is provided in the semiconductor layer 10 on the side of the other end E12 of the gate electrode 40. The drain layer 60 is an N-type (second conductivity type) semiconductor layer containing a high concentration (equal to or higher than about 10²⁰/cm³, for example) of N-type impurities (arsenic or phosphorus, for example).

The drain layer 60 is not provided just below the bottom surface Fbtm of the gate electrode 40 and does not face the bottom surface Fbtm. That is, when viewed from above the surface of the semiconductor layer 10, the drain layer 60 is not overlapped with the bottom surface Fbtm of the gate electrode 40. In other words, an end Ed of the drain layer 60 is separated from the other end E12 of the gate electrode 40 in the channel length direction, so that there is an offset region OS between the channel portion CH below the gate electrode 40 and the drain layer 60.

The pocket layer 70 of a P-type serving as a first diffusion layer is provided in the semiconductor layer 10 between the channel portion CH (first portion) and the drain layer 60. The pocket layer 70 is a P-type (first conductivity type) semiconductor layer containing a medium concentration (10¹⁸ to 10¹⁹/cm³, for example) of P-type impurities. The impurity concentration of the pocket layer 70 will be explained later.

In the first embodiment, the pocket layer 70 is adjacent to the drain layer 60 and extends from the end Ed of the drain layer 60 to just below the bottom surface Fbtm of the gate electrode 40. The pocket layer 70 is formed in such a manner that a bottom surface of the pocket layer 70 is located at a shallower position than that of the drain layer 60. The pocket layer 70 faces the bottom surface Fbtm of the gate electrode 40. That is, the pocket layer 70 is provided across an entire surface region (the offset region OS) of the semiconductor layer 10 from the end Ed of the drain layer 60 to the channel portion CH. When viewed from above the surface of the semiconductor layer 10, the pocket layer 70 is overlapped with the bottom surface Fbtm of the gate electrode 40.

The channel portion CH as the first portion is provided in a surface region of the semiconductor layer 10 between the source layer 50 and the pocket layer 70. The channel portion CH is located in the surface region of the semiconductor layer 10 facing the bottom surface Fbtm of the gate electrode 40. The channel portion CH is a P-type semiconductor layer and has an impurity concentration lower than those of the source layer 50, the drain layer 60, and the pocket layer 70. In the first embodiment, the channel portion CH is a low-concentration P-type semiconductor layer. However, the channel portion CH can be, for example, a semiconductor layer (a so-called “intrinsic semiconductor layer”) having an impurity concentration equal to or lower than about 10¹⁶/cm³ or an N-type semiconductor layer containing a low concentration of N-type impurities. Because the TFET 100 has a threshold voltage greatly depending on the impurity concentration of the channel portion CH, the threshold voltage of the TFET 100 can be adjusted by changing the impurity concentration of the channel portion CH.

The sidewall films 80 are provided on side surfaces of the gate electrode 40. For example, a silicon nitride film is used for the sidewall film 80. The sidewall films 90 are provided on the side surfaces of the gate electrode 40 via the sidewall films 80 (or with the sidewall films 80 interposed therebetween). For example, a silicon dioxide film is used for the sidewall film 90. At least parts of the sidewall films 80 and 90 are provided on the pocket layer 70.

The impurity concentration of the pocket layer 70 is explained next.

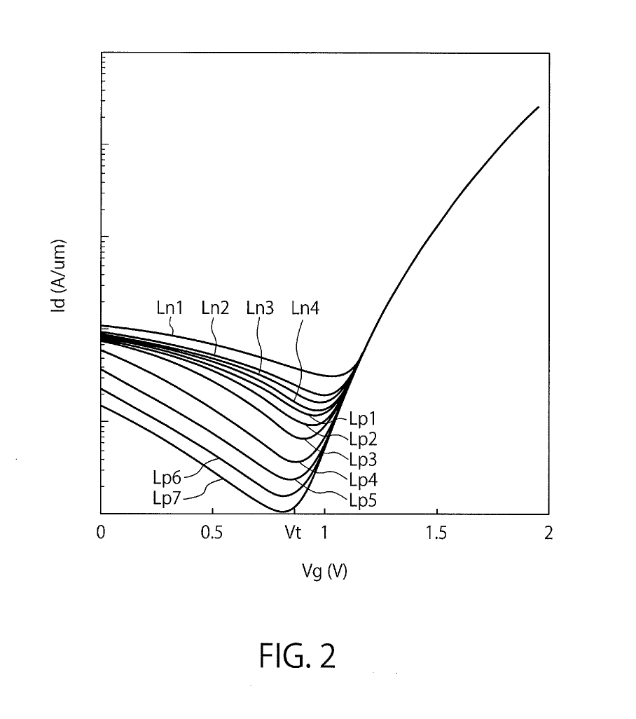

FIG. 2 is a graph showing a relation between the impurity concentration of the pocket layer 70 and the leakage current. This graph illustrates simulation results indicating Id-Vg characteristics in cases where the impurity concentration of the pocket layer 70 is changed. The vertical axis of the graph represents a drain current Id and the horizontal axis thereof represents a gate voltage Vg.

Lines Ln1 to Ln4 and Lp1 to Lp7 show results at various impurity concentrations of the pocket layer 70, respectively. The lines Ln1 to Ln4 show results in a case where the pocket layer 70 is an N-type diffusion layer and the lines Lp1 to Lp7 show results in a case where the pocket layer 70 is a P-type diffusion layer. For example, the pocket layers 70 in the cases of the lines Ln1 to Ln4 are N-type diffusion layers and have impurity concentrations of about 5×10¹⁸/cm³, about 1×10¹⁸/cm³, about 5×10¹⁷/cm³, and about 1×10¹⁷/cm³, respectively. The pocket layers 70 in the cases of the lines Lp1 to Lp7 are P-type diffusion layers and have impurity concentrations of about 1×10¹⁷/cm³, about 5×10¹⁷/cm³, about 1×10¹⁸/cm³, about 2×10¹⁸/cm³, about 3×10¹⁸/cm³, about 4×10¹⁸/cm³, and about 5×10¹⁸/cm³, respectively.

In this simulation, the TFET 100 is an N-TFET and the configuration of the TFET 100 except for the conductivity type and the impurity concentration of the pocket layer 70 is the same. Therefore, the impurity concentrations of the source layer 50 are assumed to be the same in the cases of the lines Ln1 to Ln4 and Lp1 to Lp7 and the impurity concentrations of the channel portion CH are also assumed to be the same in the cases of the lines Ln1 to Ln4 and the Lp1 to Lp7. Because a threshold voltage Vth of a BTBT part depends on the impurity concentration of a boundary part between the source layer 50 (the extension region 51) and the channel portion CH, the threshold voltages (Vth) of the TFET 100 in the cases of the lines Ln1 to Ln4 and Lp1 to Lp7 are substantially fixed.

It is assumed that the TFET 100 is brought to an on-state when the gate voltage Vg exceeds the threshold voltage Vth. In this case, the TFET 100 is in an off-state when the gate voltage Vg is lower than the threshold voltage Vth and the TFET 100 is in an on-state when the gate voltage Vg is equal to or higher than the threshold voltage Vth.

As shown by the graph of FIG. 2, the drain currents Id greatly differ among the cases of the lines Ln1 to Ln4 and Lp1 to Lp7 when the TFET 100 is in an off-state. It is known that the drain current Id flowing when the TFET 100 is in an off-state is a leakage current (hereinafter, also “off-leakage current”) flowing between the drain and the gate. As described above, it is preferable that the off-leakage current be smaller.

With reference to FIG. 2, the off-leakage current is suppressed more in the cases where the conductivity type of the pocket layer 70 is a P-type than in the cases where the conductivity type is an N-type. When the pocket layer 70 is of an N-type, which is the same as the conductivity type of the drain layer 60, the pocket layer 70 is electrically connected to the drain layer 60 and thus off-leakage between the drain and the gate via the pocket layer 70 adversely occurs.

On the other hand, when the pocket layer 70 is of a P-type opposite to the conductivity type of the drain layer 60, the pocket layer 70 forms a PN junction part with the drain layer 60 and suppresses extension of a depletion layer from the drain layer 60 when the TFET 100 is in an off-state, thereby electrically isolating the drain and the gate from each other. Therefore, in the N-TFET 100, the off-leakage current can be suppressed more in the cases where the conductivity type of the pocket layer 70 is a P-type than in the cases where the conductivity type is an N-type.

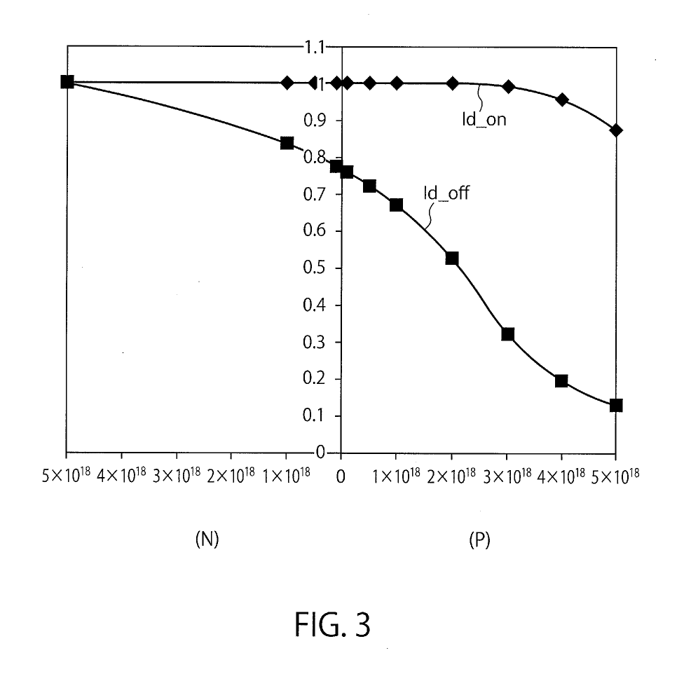

When the conductivity type of the pocket layer 70 is a P-type, the off-leakage current is suppressed more when the impurity concentration of the pocket layer 70 is higher. This is because a depletion layer is less likely to extend from the drain layer 60 when the impurity concentration of the pocket layer 70 is higher. If the impurity concentration of the pocket layer 70 is too high, a leakage current (a junction leakage current) is likely to occur at the junction part between the pocket layer 70 and the drain layer 60. To suppress the junction leakage current, it is preferable that the impurity concentration of the pocket layer 70 be equal to or lower than that of the source layer 50. It is thus preferable that the pocket layer 70 be a P-type semiconductor layer having at least a higher impurity concentration than that of the channel portion CH and having an impurity concentration equal to or lower than that of the source layer 50. This enables suppression of the off-leakage current while suppressing the junction leakage current between the pocket layer 70 and the drain layer 60. As will be described later with reference to FIG. 3, the impurity concentration of the pocket layer 70 has a desired upper limit also in terms of an on-state current.

FIG. 3 is a graph showing a relation between the off-leakage current and the on-state current. This graph illustrates simulation results of an off-leakage current Id_off (Vg=0 volt, for example) and an on-state current Id_on (Vg=1.8 volts, for example) in cases where the impurity concentration of the pocket layer 70 is changed.

The vertical axis of the graph represents the value standardized based on the off-leakage current Id_off and the on-state current Id_on when the pocket layer 70 is an N-type diffusion layer having an impurity concentration of 5×10¹⁸/cm³. That is, the vertical axis shows numerical values (ratios) of the off-leakage currents Id_off and the on-state currents Id_on of the pocket layers 70 having different impurity concentrations with respect to a case where the off-leakage current Id_off and the on-state current Id_on of the pocket layer 70 that is an N-type diffusion layer having an impurity concentration of 5×10¹⁸/cm³ are 1, respectively. The horizontal axis of the graph represents the conductivity type of the pocket layer 70 and the impurity concentration thereof. The left half of the graph in FIG. 3 shows an N-type impurity concentration and the right half thereof shows a P-type impurity concentration.

As explained with reference to FIG. 2, the off-leakage current Id_off is suppressed more in the cases where the conductivity type of the pocket layer 70 is a P-type than in the cases where the conductivity type is an N-type. When the conductivity type of the pocket layer 70 is a P-type, the off-leakage current Id_off is suppressed more when the impurity concentration of the pocket layer 70 is higher.

On the other hand, the on-state current Id_on is almost constant when the pocket layer 70 is an N-type semiconductor and when the pocket layer 70 is a P-type semiconductor having a relatively low impurity concentration. However, in the case where the pocket layer 70 is a P-type semiconductor, the on-state current Id_on starts decreasing when the impurity concentration exceeds about 3×10¹⁸/cm³. That is, when the pocket layer 70 is a P-type semiconductor having an impurity concentration above about 3×10¹⁸/cm³, the on-state current Id_on is decreased. This is because as the impurity concentration is higher, the pocket layer 70 is formed to be deeper and wider and thus a current is less likely to flow, which increases the on-resistance. Therefore, in terms of the on-state current Id_on, it is preferable that the pocket layer 70 be an N-type diffusion layer or be a P-type diffusion layer having an impurity concentration equal to or lower than about 3×10¹⁸/cm³.

As described above, while the pocket layer 70 is preferably a P-type semiconductor having a relatively high impurity concentration in terms of suppression of the off-leakage current, the P-type impurity concentration of the pocket layer 70 is preferably equal to or lower than about 3×10¹⁸/cm³ to keep a high on-state current. That is, the pocket layer 70 is preferably a P-type diffusion layer having an impurity concentration close to about 3×10¹⁸/cm³ to suppress the off-leakage current Id_off while suppressing decrease of the on-state current Id_on.

A preferable impurity concentration of the pocket layer 70 depends also on the depth of the pocket layer 70. For example, in the simulations shown in FIGS. 2 and 3, the depth of the pocket layer 70 is about 30 nanometers. Although a preferable depth of the pocket layer 70 cannot be specified unconditionally, it is preferable that the pocket layer 70 be deeper to suppress extension of a depletion layer from the drain layer 60 toward the channel portion CH in order to suppress the off-leakage current. On the other hand, to keep a high on-state current, the pocket layer 70 is preferably shallower not to interfere with the current.

As described above, the N-TFET 100 according to the first embodiment includes the P-type pocket layer 70 in the surface region of the semiconductor layer 10 between the channel portion CH and the drain layer 60. Accordingly, extension of a depletion layer from the drain layer 60 toward the channel portion CH can be suppressed and the off-leakage current between the drain and the gate can be suppressed when the TFET 100 is in an off-state.

In the first embodiment, the pocket layer 70 is provided across the entire offset region OS and extends to just below the bottom surface Fbtm of the gate electrode 40 as shown in FIG. 1. However, the pocket layer 70 is not always required to extend to just below the bottom surface Fbtm of the gate electrode 40 and can be alternatively provided at least in a part of the semiconductor layer 10 between the channel portion CH and the drain layer 60. That is, the pocket layer 70 does not need to face the bottom surface Fbtm of the gate electrode 40 and does not need to be overlapped with the bottom surface Fbtm of the gate electrode 40 when viewed from above the surface of the semiconductor layer 10. Although the pocket layer 70 is separated from the other end E12 of the gate electrode 40 and is offset from the gate electrode 40 in this case, extension of a depletion layer from the drain layer 60 can be suppressed. Therefore, even when the pocket layer 70 is offset from the gate electrode 40, the TFET 100 can achieve the effect of the first embodiment described above.

In the first embodiment, the pocket layer 70 is separated from the source layer 50 and is provided in the offset region OS between the drain layer 60 and the channel portion CH. The threshold voltage Vth of the BTBT part can be adjusted by the impurity concentration of the boundary part between the source layer 50 (the extension region 51) and the channel portion CH. Therefore, separation of the pocket layer 70 from the source layer 50 to provide the pocket layer 70 in the offset region OS between the drain layer 60 and the channel portion CH as in the first embodiment enables the off-leakage current to be suppressed without affecting the threshold voltage Vth. Accordingly, the threshold voltage Vth and the off-leakage current can be independently and separately controlled in the first embodiment. That is, the TFET 100 according to the first embodiment can achieve both decrease of the off-leakage current and decrease of the threshold voltage Vth.

In the first embodiment, the pocket layer 70 has a conductivity type (the P-type) different from that (the N-type) of the drain layer 60. The impurity concentration of the pocket layer 70 is higher than that of the channel portion CH and is equal to or lower than that of the source layer 50. Accordingly, the off-leakage current can be suppressed while the junction leakage current between the pocket layer 70 and the drain layer 60 is suppressed.

Furthermore, it is preferable that the impurity concentration of the pocket layer 70 be higher than that of the channel portion CH and be equal to or lower than 3×10¹⁸/cm³. Decrease of the on-state current in the TFET 100 can be thereby suppressed while the off-leakage current is decreased as explained with reference to the graphs in FIGS. 2 and 3.

A manufacturing method of the TFET 100 is explained next.

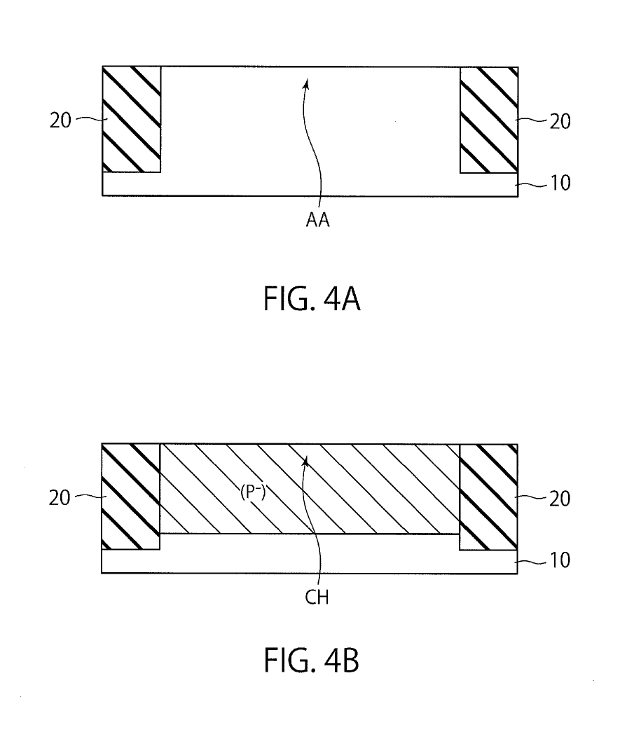

FIGS. 4A to 8B are cross-sectional views showing an example of a manufacturing method of the N-TFET 100 according to the first embodiment.

First, as shown in FIG. 4A, the element isolation part 20 is formed in the semiconductor layer 10. The semiconductor layer 10 can be a SOI layer of a SOI substrate, a SiGe layer of a SiGe-OI substrate, a Ge layer of a Ge-OI substrate, a silicon layer formed using a silicon substrate, or a semiconductor layer using a group III-V compound semiconductor substrate. Alternatively, the semiconductor layer 10 can be a semiconductor layer epitaxially grown on an arbitrary substrate. The element isolation part 20 is formed by forming a trench in the semiconductor layer 10 using a lithography technique and an etching technique and embedding an insulating film in the trench. Formation of the element isolation part 20 determines active areas AA for forming the TFET 100.

Next, P-type impurities (boron, for example) are introduced to the semiconductor layer 10 in the active areas AA using the lithography technique and an ion implantation method. Subsequently, activation annealing such as RTA (Rapid Thermal Annealing) is performed to form a P-type channel portion CH as shown in FIG. 4B. When an N-type channel portion CH is to be formed, it suffices to introduce N-type impurities (arsenic or phosphorus, for example) to the semiconductor layer 10.

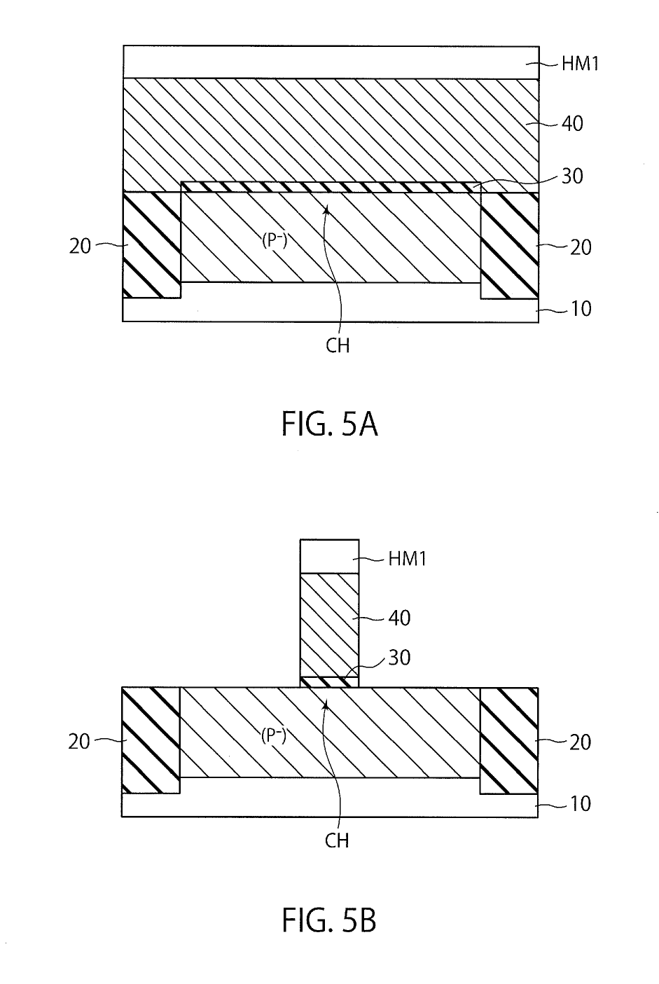

Next, as shown in FIG. 5A, the gate dielectric film 30 is formed on the semiconductor layer 10. The gate dielectric film 30 can be a thermal oxide film obtained by thermally oxidizing the semiconductor layer 10 or can be a TEOS (Tetraethylorthosilicate) film, a silicon nitride film (Si₃N₄), a SiON film, or a high dielectric film such as HfO₂ formed by a CVD (Chemical Vapor Deposition) method.

Subsequently, a material of the gate electrode 40 is deposited on the gate dielectric film 30 using the CVD method. The material of the gate electrode 40 is, for example, polysilicon. N-type impurities (arsenic or phosphorus, for example) are introduced to the material of the gate electrode 40 using the ion implantation method. The gate electrode 40 thereby becomes N-doped polysilicon. The material of the gate electrode 40 can be an electrically-conducting material other than doped polysilicon, such as metal.

Next, a material of a hard mask HM1 is deposited on the material of the gate electrode 40 using the CVD method. The material of the hard mask HM1 is an insulating film such as a silicon nitride film. A structure shown in FIG. 5A is thereby obtained.

Subsequently, the material of the hard mask HM1 is processed in layout patterns of the gate electrode 40 using the lithography technique and a RIE (Reactive Ion Etching) method. The material of the gate electrode 40 is then processed by the RIE method using the processed hard mask HM1 as a mask. Next, the gate dielectric film 30 is processed, for example, by a wet etching method using DHF (Diluted Hydrogen Fluoride). Accordingly, the gate dielectric film 30 is formed on the semiconductor layer 10 and the gate electrode 40 is formed on the gate dielectric film 30 as shown in FIG. 5B.

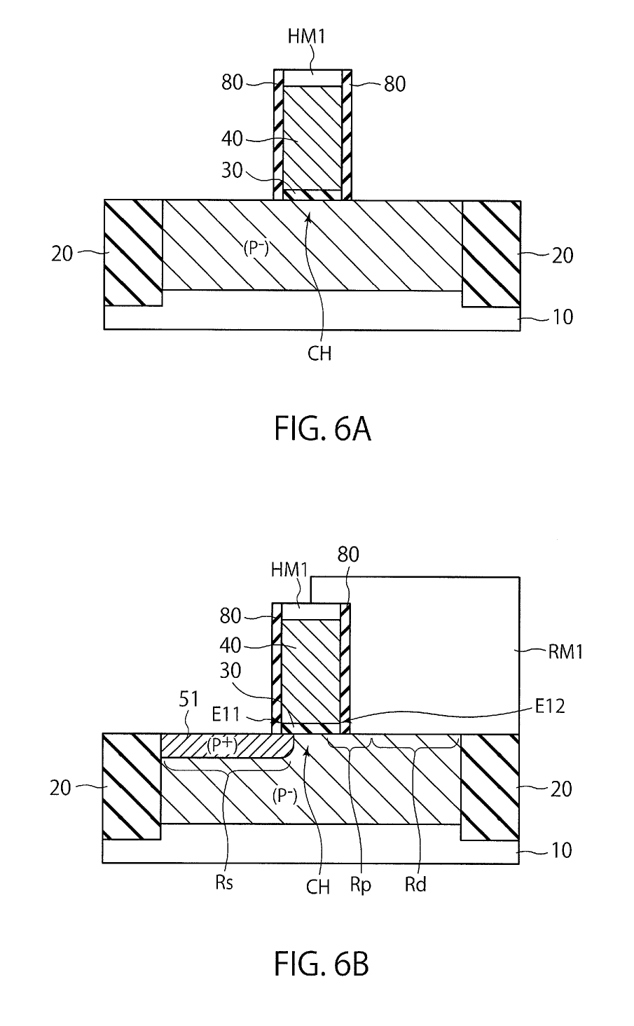

Subsequently, a material of the sidewall films 80 is deposited on the semiconductor layer 10, on the hard mask HM1, and on side surfaces of the gate electrode 40 using the CVD method. The material of the sidewall films 80 is an insulating film such as a silicon nitride film and a film thickness thereof is, for example, several nanometers. Next, the material of the sidewall films 80 is etched back using the RIE method, whereby the sidewall films 80 are left on the side surfaces of the gate electrode 40 as shown in FIG. 6A.

Subsequently, a drain-layer formation region Rd and a pocket-layer formation region (first-diffusion-layer formation region) Rp of the semiconductor layer 10 on the side of the other end E12 of the gate electrode 40 are covered with a resist film RM1 serving as a first mask material using the lithography technique. Next, as shown in FIG. 6B, P-type impurities (boron, for example) for forming the extension region 51 are introduced to a source-layer formation region Rs of the semiconductor layer 10 on the side of the one end E11 of the gate electrode 40 using the resist film RM1 as a mask.

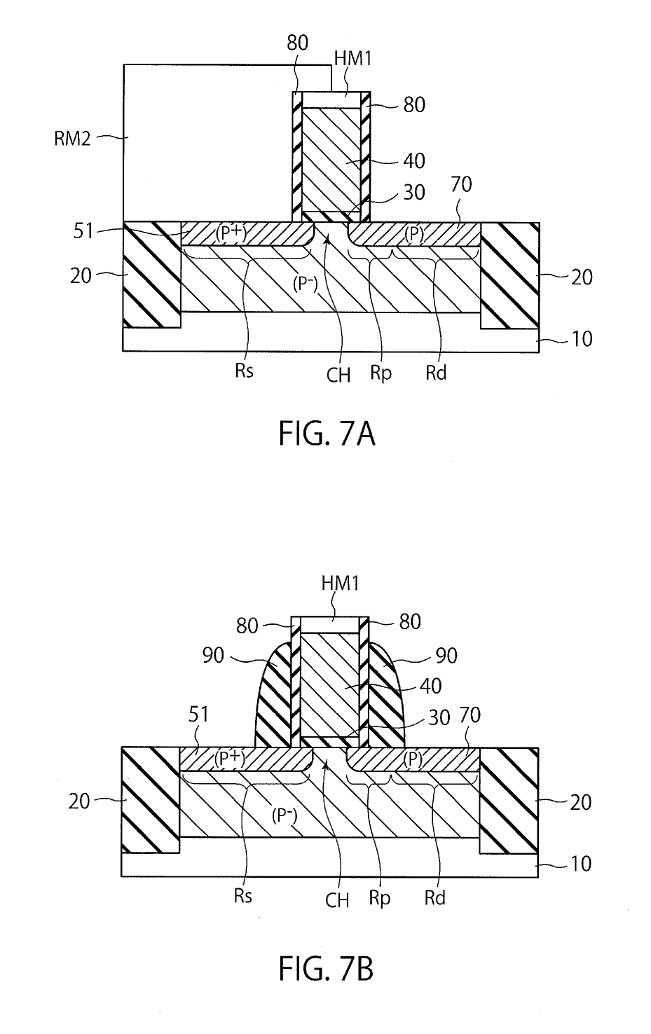

After removal of the resist film RM1, the source-layer formation region Rs of the semiconductor layer 10 is covered with a resist film RM2 serving as a second mask material using the lithography technique. Subsequently, as shown in FIG. 7A, P-type impurities (boron, for example) for forming the pocket layer 70 are introduced to the drain-layer formation region Rd and the pocket-layer formation region Rp using the resist film RM2 as a mask. The concentration of the P-type impurities introduced at that time is higher than that of the P-type impurities for forming the channel portion CH explained with reference to FIG. 4B and is equal to or lower than that of the P-type impurities for forming the extension region 51 explained with reference to FIG. 6B.

When the impurity concentration of the pocket layer 70 can be similar to that of the extension region 51, introduction of the impurities to the drain-layer formation region Rd and the pocket-layer formation region Rp shown in FIG. 7A can be performed in the same process as that of introduction of the impurities to the source-layer formation region Rs shown in FIG. 6B. That is, the impurities of the extension region 51 and the impurities of the pocket layer 70 can be introduced in the same ion implantation process. In this case, the resist film RM1 in FIG. 6B and the resist film RM2 in FIG. 7A are not required. Alternatively, after the introduction of the impurities to the extension region 51 shown in FIG. 6B, the introduction of the P-type impurities can be performed without forming the resist film RM2 in FIG. 7A.

Next, after removal of the resist film RM2, a material of the sidewall films 90 is deposited on the semiconductor layer 10, on the hard mask HM1, and on the sidewall films 80 located on the side surfaces of the gate electrode 40 using the CVD method. The material of the sidewall films 90 is an insulating film such as a silicon dioxide film and a film thickness thereof is, for example, several tens of nanometers. Subsequently, the sidewall films 90 are etched back using the RIE method, whereby the sidewall films 90 are left on the side surfaces of the gate electrode 40 as shown in FIG. 7B. The sidewall film 90 is provided on the side surface of the gate electrode 40 via the sidewall film 80 (with the sidewall film 80 interposed therebetween) and is provided on the pocket-layer formation region Rp.

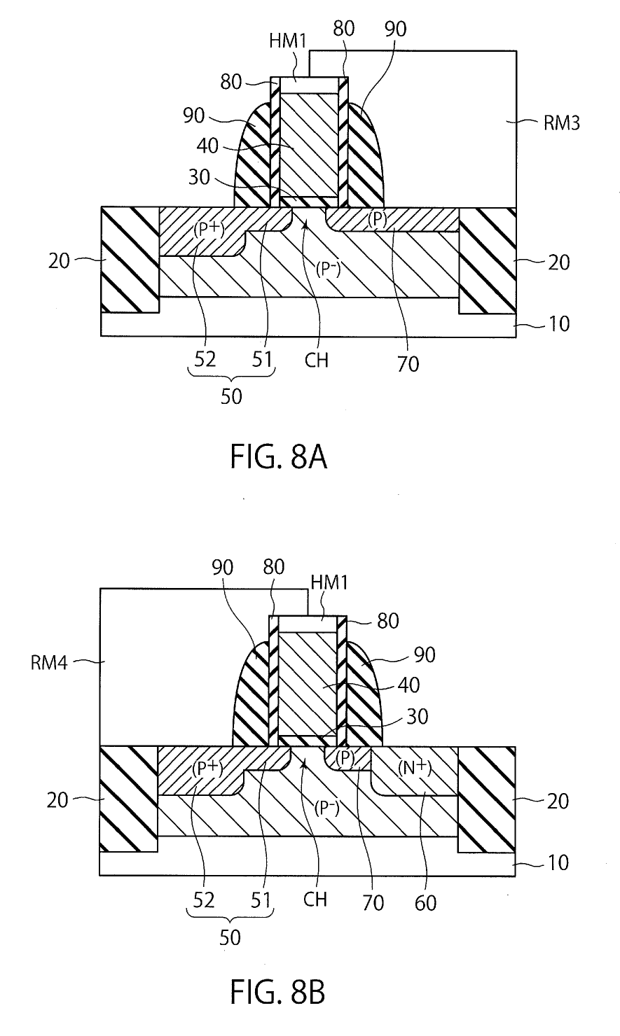

Next, the drain-layer formation region Rd is covered with a resist film RM3 using the lithography technique. Subsequently, as shown in FIG. 8A, P-type impurities (boron, for example) for forming the source region 52 are introduced to the semiconductor layer 10 in the source-layer formation region Rs using the resist film RM3 and the sidewall film 90 as a mask.

After removal of the resist film RM3, the source-layer formation region Rs of the semiconductor layer 10 is covered with a resist film RM4 serving as a third mask material using the lithography technique. Next, as shown in FIG. 8B, N-type impurities (arsenic or phosphorus, for example) for forming the drain layer 60 are introduced to the semiconductor layer 10 in the drain-layer formation region Rd using the resist film RM4 and the sidewall film 90 as a mask. The concentration of the N-type impurities introduced at that time is set at a sufficiently higher value than that of the P-type impurities introduced to form the pocket layer 70. Accordingly, the semiconductor layer 10 in the drain-layer formation region Rd is changed from the P-type to the N-type, which enables the N-type drain layer 60 to be formed. Because the N-type impurities for forming the drain layer 60 are not introduced to the pocket-layer formation region Rp under the sidewall film 90, the pocket-layer formation region Rp under the sidewall film 90 is kept as a P-type as shown in FIG. 8B. Therefore, the pocket layer 70 can be formed under the sidewall film 90.

After removal of the resist film RM4, the hard mask HM1 is removed using a hot phosphoric acid solution or the like.

Next, the impurities in the source layer 50, the drain layer 60, and the pocket layer 70 are activated using spike annealing. The source layer 50, the drain layer 60, and the pocket layer 70 are thereby formed.

Thereafter, an interlayer dielectric film, contacts, wires, and the like are formed, thereby completing the TFET 100 according to the first embodiment.

As described above, according to the first embodiment, the pocket layer 70 having a conductivity type (the P-type) different from that (the N-type) of the drain layer 60 is formed in the surface region of the semiconductor layer 10 between the channel portion CH and the drain layer 60. The off-leakage current between the drain and the gate can be thereby suppressed. The pocket layer 70 is formed on the side of the drain layer 60 and is separated from the boundary part between the source layer 50 and the channel portion CH that affects the threshold voltage Vth. Therefore, both decrease of the off-leakage current and decrease of the threshold voltage Vth can be achieved.

Furthermore, in the first embodiment, the impurity concentration of the pocket layer 70 is higher than that of the channel portion CH and is equal to or lower than that of the source layer 50. More preferably, the impurity concentration of the pocket layer 70 is equal to or lower than 3×10¹⁸/cm³. This enables suppression of the junction leakage current between the pocket layer 70 and the drain layer 60 or the off-leakage current while keeping a high on-state current.

### Second Embodiment

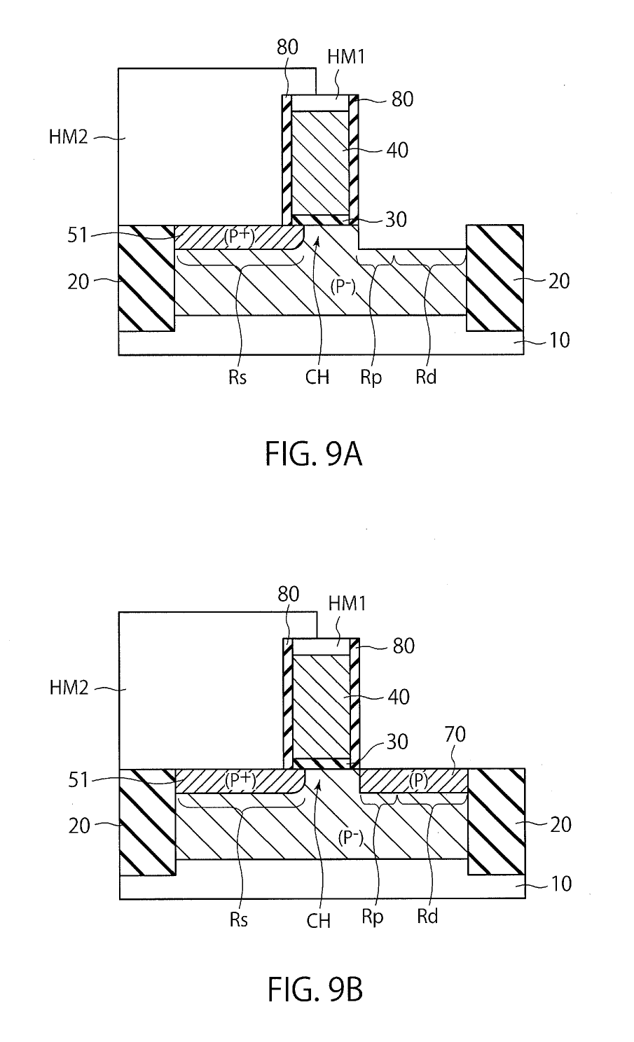

FIGS. 9A and 9B are cross-sectional views showing an example of a manufacturing method of an N-TFET 100 according to a second embodiment. The second embodiment is different from the first embodiment in that the pocket layer 70 is formed of an epitaxial layer. However, the configuration of the TFET according to the second embodiment is substantially the same as that of the TFET according to the first embodiment.

A manufacturing method of the N-TFET 100 according to the second embodiment is explained below.

First, the processes as explained with reference to FIGS. 4A to 6B are performed.

Next, after removal of the resist film RM1, a material of a hard mask HM2 serving as a second mask material is deposited on the semiconductor layer 10 using the CVD method. The material of the hard mask HM2 is an insulating film such as a silicon nitride film.

Subsequently, the material of the hard mask MH2 on the drain-layer formation region Rd and the pocket-layer formation region Rp is removed using the lithography technique and the RIE method with the hard mask HM2 on the source-layer formation region Rs left as shown in FIG. 9A.

Next, as shown in FIG. 9A, the semiconductor layer 10 in the drain-layer formation region Rd and the pocket-layer formation region Rp is etched by the RIE method using the hard mask HM2 as a mask. Accordingly, a part of the semiconductor layer 10 in the drain-layer formation region Rd and the pocket-layer formation region Rp is removed.

Subsequently, as shown in FIG. 9B, an epitaxial layer containing P-type impurities is grown in the drain-layer formation region Rd and the pocket-layer formation region Rp using the hard mask HM2 as a mask. The pocket layer 70 is thereby formed. An impurity concentration of the pocket layer 70 (the epitaxial layer) according to the second embodiment can be identical to that of the pocket layer 70 according to the first embodiment.

Thereafter, the processes as explained with reference to FIGS. 7B to 8B are performed, thereby completing the TFET 100 according to the second embodiment.

In the second embodiment, the pocket layer 70 is formed of an epitaxial layer. The epitaxial layer is higher in the controllability than a diffusion layer formed by the ion implantation method and can be formed at a high impurity concentration in a shallow (narrow) region. That is, the pocket layer 70 according to the second embodiment can have a steeper concentration profile than the pocket layer 70 according to the first embodiment. Accordingly, interference of a flow of an on-state current can be prevented while extension of a depletion layer from the drain layer 60 to the channel portion CH in the surface region of the semiconductor layer 10 is effectively suppressed. That is, the TFET 100 according to the second embodiment can more reliably suppress decrease of the on-state current while suppressing the off-leakage current. Further, the second embodiment can achieve identical effects as those of the first embodiment.

In the above embodiments, the formation order of the extension region 51 and the pocket layer 70 can be reversed and the formation order of the source region 52 and the drain layer 60 can be reversed.

Furthermore, while the N-TFET has been explained in the above embodiments, these embodiments can be readily applied also to a P-TFET by changing the conductivity types of the impurities. In the P-TFET, the source layer 50 and the pocket layer 70 are N-type semiconductor layers and the drain layer 60 is a P-type semiconductor layer. The impurity concentration of the N-type pocket layer 70 in this case can be identical to that of the P-type pocket layer 70 in the above embodiments.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a semiconductor layer;
a gate dielectric film on the semiconductor layer;
a gate electrode on the semiconductor layer via the gate dielectric film;
a first conductivity-type source layer in the semiconductor layer on a side of one end of the gate electrode;
a second conductivity-type drain layer in the semiconductor layer on a side of the other end of the gate electrode, the drain layer not facing a bottom surface of the gate electrode; and
a first diffusion layer of the first conductivity-type provided at least in a part of the semiconductor layer between a first portion of the semiconductor layer and the drain layer, the first portion facing the bottom surface of the gate electrode.

2. The device of claim 1, wherein the first diffusion layer is provided from an end of the drain layer to the first portion.

3. The device of claim 2, wherein at least a part of the first diffusion layer faces the bottom surface of the gate electrode.

4. The device of claim 1, wherein the first diffusion layer has an impurity concentration higher than that of the first portion.

5. The device of claim 1, wherein the first diffusion layer has an impurity concentration equal to or lower than 3×10¹⁸/cm³.

6. The device of claim 1, wherein the first diffusion layer has an impurity concentration equal to or lower than that of the source layer.

7. The device of claim 1, wherein a bottom surface of the first diffusion layer is shallower than that of the drain layer.

8. The device of claim 1, wherein at least a part of the source layer faces the bottom surface of the gate electrode.

9. The device of claim 1, wherein
the first portion is a semiconductor layer of the first conductivity-type or the second conductivity-type, and
the first portion has an impurity concentration lower than those of any of the source layer, the drain layer, and the first diffusion layer.

10. A manufacturing method of a semiconductor device, the method comprising:
forming a gate dielectric film on a semiconductor layer;
forming a gate electrode on the gate dielectric film;
introducing first conductivity-type impurities for forming a source layer to a source-layer formation region of the semiconductor layer on a side of one end of the gate electrode, and introducing the first conductivity-type impurities for forming a first diffusion layer to a drain-layer formation region and a first-diffusion-layer formation region of the semiconductor layer on a side of the other end of the gate electrode;
forming a sidewall film on a side surface of the gate electrode and over the first-diffusion-layer formation region; and
introducing second conductivity-type impurities for forming a drain layer to the drain-layer formation region using at least the sidewall film as a mask.

11. The method of claim 10, wherein
a first mask material covering the drain-layer formation region and the first-diffusion-layer formation region is used as a mask when the first conductivity-type impurities are introduced to the source-layer formation region,
a second mask material covering the source-layer formation region is used as a mask when the first conductivity-type impurities are introduced to the drain-layer formation region and the first-diffusion-layer formation region, and
a third mask material covering the source-layer formation region and the sidewall film are used as a mask when the second conductivity-type impurities are introduced to the drain-layer formation region.

12. The method of claim 10, wherein introduction of the first conductivity-type impurities to the drain-layer formation region and the first-diffusion-layer formation region is performed in a same process as that of introduction of the first conductivity-type impurities to the source-layer formation region.

13. The method of claim 10, wherein the first diffusion layer is formed under the sidewall film.

14. The method of claim 10, wherein the first diffusion layer has an impurity concentration higher than that of a first portion of the semiconductor layer and equal to or lower than that of the source layer, the first portion facing a bottom surface of the gate electrode.

15. The method of claim 10, further comprising introducing the first conductivity-type impurities to the source-layer formation region using at least the sidewall film as a mask after formation of the sidewall film.

16. A manufacturing method of a semiconductor device, the method comprising:
forming a gate dielectric film on a semiconductor layer;
forming a gate electrode on the gate dielectric film;
introducing first conductivity-type impurities for forming a source layer to a source-layer formation region of the semiconductor layer on a side of one end of the gate electrode while removing a part of the semiconductor layer in a drain-layer formation region and a first-diffusion-layer formation region on a side of the other end of the gate electrode, and forming an epitaxial layer in the removed part of the semiconductor layer in the drain-layer formation region and the first-diffusion-layer formation region, the epitaxial layer containing the first conductivity-type impurities for forming a first diffusion layer;
forming a sidewall film on a side surface of the gate electrode and over the first-diffusion-layer formation region having the epitaxial layer formed therein; and
introducing second conductivity-type impurities for forming a drain layer to the epitaxial layer in the drain-layer formation region using at least the sidewall film as a mask.

17. The method of claim 16, wherein
a first mask material covering the drain-layer formation region and the first-diffusion-layer formation region is used as a mask when the first conductivity-type impurities are introduced to the source-layer formation region,
a second mask material covering the source-layer formation region is used as mask when the epitaxial layer is formed in the drain-layer formation region and the first-diffusion-layer formation region, and
a third mask material covering the source-layer formation region and the sidewall film are used as a mask when the second conductivity-type impurities are introduced to the drain-layer formation region.

18. The method of claim 16, wherein the first diffusion layer is formed under the sidewall film.

19. The method of claim 16, wherein the first diffusion layer has an impurity concentration higher than that of a first portion of the semiconductor layer and equal to or lower than that of the source layer, the first portion facing a bottom surface of the gate electrode.

20. The method of claim 16, further comprising introducing the first conductivity-type impurities to the source-layer formation region using at least the sidewall film as a mask after formation of the sidewall film.
